(19) United States
(12) Patent Application Publication
(10) Pub. No.: US 2025/0290596 A1
(43) Pub. Date: Sep. 18, 2025

(54) FLOATING MOVING OBJECT AND PROBE MECHANISM

(71) Applicant: THK CO., LTD., Tokyo (JP)

(72) Inventors: Jun KAWASAKI, Minato-ku, Tokyo (JP); Masaki SHIBUYA, Minato-ku, Tokyo (JP); Norimasa OKADA, Minato-ku, Tokyo (JP); Hiroaki MOCHIZUKI, Minato-ku, Tokyo (JP); Eiji HOSAKA, Minato-ku, Tokyo (JP); Hiroomi KURIBAYASHI, Minato-ku, Tokyo (JP)

(73) Assignee: THK CO., LTD., Tokyo (JP)

(21) Appl. No.: 18/858,991

(22) PCT Filed: Apr. 13, 2023
(86) PCT No.: PCT/JP2023/015080

§ 371 Date: Oct. 22, 2024

(30) Foreign Application Priority Data
Apr. 26, 2022 (JP) 2022-072006
Mar. 29, 2023 (JP) 2023-053605

(51) Int. Cl. F16M 13/02; B64U 10/13; B64U 101/26; F03D 17/00

(52) U.S. Cl. CPC F16M 13/02; B64U 10/13; B64U 2101/26; F03D 17/004

(57) ABSTRACT

Provided are a base member 11 to which one end of a spring 13 is connected, and a shaft 12 to which the other end of the spring 13 is connected, and which is configured to move relative to the base member in a direction of a central axis of the shaft when the shaft comes into contact with a target object, wherein the spring 13 is arranged such that a center axis of the spring 13 is at an angle to the center axis of the shaft.

### TECHNICAL FIELD

The present invention relates to a floating moving object and a probe mechanism.

### BACKGROUND ART

In recent years, unmanned aerial vehicles have been used for various purposes, and their development has been actively pursued. As the unmanned aerial vehicles, there are used an unmanned helicopter that is radio-controlled, a so-called drone, and the like. Here, a technique is known in which an arm is attached to an unmanned aerial vehicle to perform various operations (for example, see Patent Literature 1). Patent Literature 1 describes that a change in the center of gravity when fruit is held by the arm is offset by the movement of a battery or a motor to stabilize the airframe of the aerial vehicle.

### CITATION LIST

### Patent Literature

Patent Literature 1: Japanese Translated Patent Publication No. 2019-537161

### SUMMARY OF INVENTION

### Technical Problem

It is conceivable that an unmanned aerial vehicle could be used to inspect a structure. For example, a receptor of a wind power generator can be inspected. At this time, a probe attached to a drone is brought into contact with the receptor of the wind power generator to check electrical continuity. However, when the probe attached to the drone is brought into contact with the receptor, the attitude of the drone may become unstable due to a reaction force from the receptor. In particular, an impact at the time of contact and a sudden loss of the reaction force when the airframe of the drone leaves the contact state are significant. In addition, in cases where the probe is fixed to the drone body, the airframe is caused to rotate due to the reaction force generated when the drone tries to move forward beyond the contact position, while the airframe immediately moves away from the contact state when moving back even slightly, and hence, there is a high degree of difficulty in maintaining just a good contact state. In contrast to this, for example, by providing a compression spring, the impact at the time of contact and the sudden loss of the reaction force at the time of separation can be alleviated by gradually changing the reaction force as the probe moves forward and backward within the range of the stroke of the compression spring in a state where the probe is in contact with the receptor. At the same time, the contact can be maintained without generating an excessive reaction force even if the position of the airframe fluctuates within the stroke range.

However, the use of the compression spring increases the overall length of the probe, and may increase the mass of the unmanned aerial vehicle. Further, for example, the compression spring needs to secure a space for accommodating the spring in the most contracted state thereof, and the overall length of the probe is increased by the space. In addition, the reaction force generated by the compression spring provided in the probe is proportional to the displacement of the spring. Here, considering the absorption of the impact and the stabilization of the control of the drone, it is preferable that the reaction force of the spring immediately after the probe comes into contact with the receptor be small. This is also true for the reduction of the reaction force when the airframe moves away from the contact state. That is, when the probe comes into contact with the receptor, a sudden increase in the reaction force can make it difficult to control the airframe so that the attitude of the airframe may become unstable. Therefore, it is preferable that the change in the reaction force be gradual. On the other hand, in cases where the airframe is too close to the wind power generator, there is a risk of the airframe coming into contact with the wind power generator, and thus it is preferable to push back the airframe strongly. However, in cases where a spring constant of the compression spring is set so that the reaction force of the spring immediately after the probe contacts the receptor is small, it may be difficult to generate a reaction force that strongly pushes back the airframe even when the airframe is too close to the wind power generator.

The present invention has been made in view of the above-described various circumstances, and an object of the present invention is to bring a floating moving object into contact with a target object with an appropriate pressure.

### Solution to Problem

One aspect of the present invention is directed to a floating moving object comprising:
a base member to which one end of a spring is connected; and
a shaft to which the other end of the spring is connected, the shaft being configured to move relative to the base member in a direction of a central axis of the shaft when the shaft comes into contact with a target object;
wherein the spring is arranged such that a central axis of the spring is at an angle to the central axis of the shaft.

In addition, another aspect of the present invention is directed to a probe mechanism comprising:
a base member to which one end of a tension spring is connected; and
a shaft to which the other end of the tension spring is connected, the shaft being configured to move relative to the base member in a direction of a central axis of the shaft when the shaft comes into contact with a target object;
wherein the base member includes a guide that supports the shaft so as to be movable in the direction of the central axis of the shaft;
the other end of the tension spring is connected at a side from the guide in a direction in which the shaft moves relative to the base member when the shaft comes into contact with the target object; and
the tension spring is arranged such that a central axis of the tension spring is orthogonal to the central axis of the shaft before the shaft comes into contact with the target object, and such that an angle formed by the central axis of the tension spring and the central axis of the shaft becomes smaller as the base member approaches the target object after the shaft comes into contact with the target object.

### Advantageous Effects of Invention

According to the present invention, it is possible to bring a floating moving object into contact with a target object with an appropriate pressure.

### BRIEF DESCRIPTION OF DRAWINGS

FIG. 1 is a view illustrating an example of a schematic configuration of a drone for inspecting a wind power generator according to an embodiment.

FIG. 2 is a view illustrating an example of a schematic configuration of a drone including a probe mechanism according to a first embodiment.

FIG. 3 is a view illustrating an example of a schematic configuration of the probe mechanism according to the first embodiment.

FIG. 4 is a view of the probe mechanism in a state immediately after coming into contact with a target object, as seen from above, according to the embodiment.

FIG. 5 is a view illustrating a state in which the drone is moving forward after the probe mechanism comes into contact with the target object, as seen from above, according to the embodiment.

FIG. 6 is a view illustrating a state immediately after the drone has moved backward from the state illustrated in FIG. 5, as seen from above, according to the embodiment.

FIG. 7 is a view illustrating a state in which the drone is in the middle of moving backward, as seen from above, according to the embodiment.

FIG. 8 is a view comparing a conventional probe using a compression spring with the probe mechanism according to the embodiment.

FIG. 9 is a view for explaining a relationship between an amount of movement of a shaft and a reaction force according to the embodiment.

FIG. 10 is a view summarizing whether or not reaction forces generated on lines L1, L2, L3, and L4 satisfy requirements.

FIG. 11 is a view illustrating an example of a schematic configuration of a probe mechanism according to a second embodiment.

FIG. 12 is a view of the probe mechanism illustrating a state before a shaft and a conductive wire come into contact with a target object, as seen from above, according to the second embodiment.

FIG. 13 is a view of the probe mechanism illustrating a state after the shaft or the conductive wire comes into contact with the target object, as seen from above, according to the second embodiment.

FIG. 14 is a view illustrating an example of a schematic configuration of a probe mechanism according to a third embodiment.

### DESCRIPTION OF EMBODIMENTS

A floating moving object according to the present invention includes a base member to which one end of a spring is connected, and a shaft to which the other end of the spring is connected, the shaft being configured to move relative to the base member in a direction of a central axis of the shaft when the shaft comes into contact with a target object. Then, the spring is arranged such that a central axis of the spring is at an angle to the central axis of the shaft.

When a tip of the shaft comes into contact with the target object, the shaft can move relative to the base member in the direction of the central axis of the shaft. A member for inspecting the target object, for example, can be attached to the tip of this shaft. The spring is connected to the shaft. Note that the spring does not necessarily have to be directly connected to the shaft, but may be connected to the shaft via a member fixed to the shaft. This spring is connected at one end to the base member and is expanded by movement of the shaft relative to the base member. Since an elastic force occurs in the spring thus expanded, the spring generates the elastic force to return the shaft, which has been moved due to contact with the target object, to its original position.

The spring is arranged in such a manner that its central axis has an angle to the central axis of the shaft. That is, the spring is arranged in such a manner that the central axis of the spring and the central axis of the shaft are not parallel to each other. Since the other end of the spring is connected to the shaft, the position of the other end of the spring changes as the shaft moves, and thus the angle between the central axis of the shaft and the central axis of the spring changes. As the spring extends, the elastic force generated in the direction of the central axis of the spring becomes larger, and further, as the spring extends, the angle formed by the central axis of the shaft and the central axis of the spring becomes smaller. Therefore, as the spring extends, a component of the elastic force in the direction of the central axis of the shaft increases. Therefore, the force pushing back the shaft increases nonlinearly as the shaft moves, and thus the reaction force received by the shaft from the target object also increases nonlinearly.

Immediately after the shaft comes into contact with the target object, an amount of increase in the reaction force with respect to an amount of increase in the amount of movement of the shaft (hereinafter, also referred to as a rate of increase in the reaction force) is small, and thus it is possible to suppress a rapid increase in the reaction force. This makes it easier to control the moving object, so that it is possible to suppress the attitude of the moving object from becoming unstable. On the other hand, as the amount of movement of the shaft becomes larger, the rate of increase in the reaction force also becomes larger, and thus the reaction force increases rapidly. As a result, before any portion of the moving object other than the shaft comes into contact with the target object, a large force pushing back the moving object is suddenly generated, thus making it possible to push back the moving object strongly. Therefore, it is possible to suppress the portions of the moving object other than the shaft from coming into contact with the target object.

In addition, the spring may be a tension spring, and the spring may be arranged such that the angle formed by the central axis of the spring and the central axis of the shaft becomes smaller as the base member approaches the target object after the shaft comes into contact with the target object. As the base member approaches the target object, the angle formed by the central axis of the spring and the central axis of the shaft becomes smaller, so that a larger force can be applied to the shaft, and thus a larger reaction force can be obtained. Therefore, the moving object can be suppressed from coming into contact with the target object. Further, the angle formed by the central axis of the spring and the central axis of the shaft is large immediately after the shaft comes into contact with the target object, so that the reaction force is small, and the rate of increase in the reaction force due to the movement of the shaft is also small, thus making it easy to control the moving object.

Moreover, the base member may be provided with a guide that supports the shaft so as to be movable in the central axis direction thereof, and the other end of the spring may be connected at a side from the guide in a direction in which the shaft moves relative to the base member when coming into contact with the target object. With the base member provided with the guide, the shaft can be moved with respect to the base member in the direction of the central axis of the shaft. Further, since the other end of the spring is connected at a side from the guide in the moving direction of the shaft, the spring can be expanded with the movement of the shaft. For the guide, for example, a linear bush can be adopted.

In addition, the spring may be arranged such that the central axis of the spring is orthogonal to the central axis of the shaft before the shaft comes into contact with the target object. When the central axis of the spring is orthogonal to the central axis of the shaft, for example, even if an elastic force is generated in the spring, no force is generated in the direction in which the shaft is moved. Therefore, the elastic force immediately after the contact of the shaft with the target object can be reduced. On the other hand, when the shaft comes into contact with and is pushed by the target object, the shaft moves relative to the base member. Thus, the angle formed by the central axis of the spring and the central axis of the shaft becomes smaller than 90 degrees. Accordingly, an elastic force is generated in a direction in which the shaft is brought into contact with the target object. Also, the elastic force can be made larger as the shaft moves.

Moreover, the spring may be arranged in such a manner that, after the shaft comes into contact with the target object, when the amount of movement of the shaft is smaller than a target amount of movement, a ratio of the amount of increase in the reaction force to the amount of increase in the amount of movement of the shaft is less than a predetermined value, whereas when the amount of movement of the shaft is larger than the target amount of movement, the ratio of the amount of increase in the reaction force to the amount of increase in the amount of movement of the shaft is larger than the predetermined value. As described above, as the shaft moves after coming into contact with the target object, the angle formed by the shaft and the spring becomes smaller and the spring extends, so that the reaction force increases nonlinearly. Here, when the amount of movement of the shaft is smaller than the target amount of movement, it is easier to control the moving object if the ratio of the amount of increase in the reaction force to the amount of increase in the amount of movement of the shaft (hereinafter, also referred to as a rate of increase in the reaction force) is relatively small. In this case, by arranging the spring in such a manner that the rate of increase in the reaction force is less than a predetermined value, it becomes easier to control the moving object. On the other hand, when the amount of movement of the shaft is larger than the target amount of movement, a relatively large rate of increase in the reaction force can suppress the moving object from coming into contact with the target object. In this case, by arranging the spring in such a manner that the rate of increase in the reaction force becomes larger than the predetermined value, it is possible to suppress the moving object from coming into contact with the target object. Here, the rate of increase in the reaction force may vary depending on, for example, the spring constant and the length of the spring before the shaft comes into contact with the target object. Therefore, by determining the spring constant, the length of the spring before the shaft comes into contact with the target object, etc., so as to satisfy the above-described conditions and arranging the spring, it is possible to achieve both of reducing the rate of increase in the reaction force when the amount of movement of the shaft is smaller than the target amount of movement and increasing the rate of increase in the reaction force when the amount of movement of the shaft is larger than the target amount of movement. Note that the predetermined value is a rate of increase in the reaction force when the amount of movement of the shaft is the target amount of movement, and is a rate of increase that becomes a boundary between a rate of increase that stabilizes the attitude of the moving object and a rate of increase that strongly pushes back the moving object.

Further, a probe mechanism according to the present invention includes: a base member to which one end of a tension spring is connected; and a shaft to which the other end of the tension spring is connected, the shaft being configured to move relative to the base member in a direction of a central axis of the shaft when the shaft comes into contact with a target object; wherein the base member includes a guide that supports the shaft in a manner to be movable in the direction of the central axis thereof, and the other end of the tension spring is connected at a side from the guide in a direction in which the shaft moves relative to the base member when the shaft comes into contact with the target object; and the tension spring is arranged such that a central axis of the tension spring is orthogonal to the central axis of the shaft before the shaft comes into contact with the target object, and such that an angle formed by the central axis of the tension spring and the central axis of the shaft becomes smaller as the base member approaches the target object after the shaft comes into contact with the target object.

Here, note that the probe is a tool for contacting and examining the target object, and the shape of the probe is not limited to a needle shape. In addition, the probe mechanism can be provided on, but not limited to, a floating moving object.

Hereinafter, embodiments for carrying out the present invention will be described with reference to the drawings. However, the dimensions, materials, shapes, relative arrangements and the like of constituent components described in the embodiments are not intended to limit the scope of the present invention to those alone unless otherwise specified. In addition, the following embodiments can be combined with one another as long as such combinations are possible and appropriate.

### First Embodiment

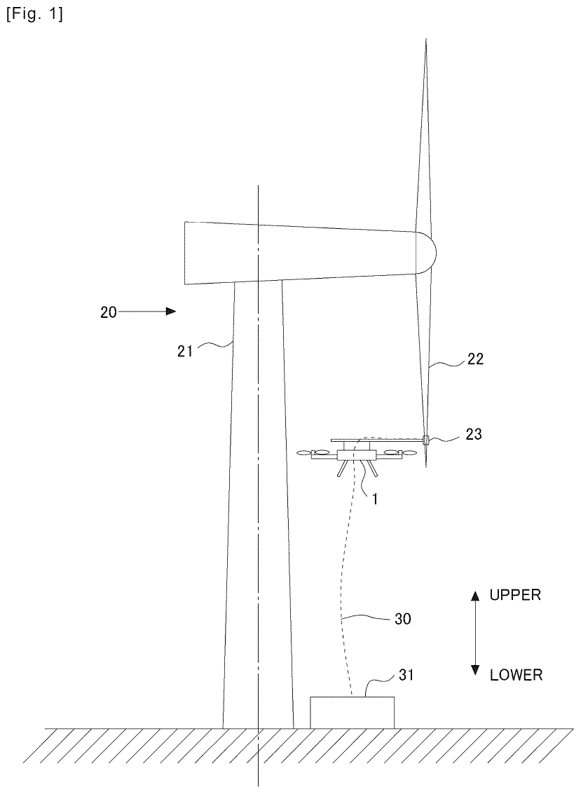

In a first embodiment, a drone 1 for inspecting a wind power generator 20 will be described as an example. FIG. 1 is a view illustrating an example of a schematic configuration of the drone 1 for inspecting the wind power generator 20 according to the embodiment. The wind power generator 20 includes a tower 21 standing on the ground and a blade 22 provided at an upper portion of the tower 21 and configured to be rotated by receiving wind. Note that the drone 1 is an example of a floating moving object.

The drone 1 is, for example, one that inspects a receptor 23 attached to the blade 22 of the wind power generator 20. Here, the wind power generator 20 may be provided with the receptor 23 in order to suppress damage due to lightning strikes. The receptor 23 is connected to a ground electrode via an electric line or the like, through which a current of lightning flows from the receptor 23 to the ground electrode.

Whether or not the electric line from the receptor 23 to the ground electrode is continuous is inspected by the drone 1. For example, a current value may be detected when the drone 1 applies a voltage to the receptor 23. Therefore, since the drone 1 also needs to be connected to the ground electrode via an electric line, a wire 30 leading to the ground electrode is connected to the drone 1. This wire 30 may include an electric line for controlling the drone 1 or an electric line for supplying electric power to the drone 1. The wire 30 is connected to an inspection device 31 for inspecting the receptor 23. The inspection device 31 is a device for inspecting electrical continuity of the electric wire from the receptor 23 to the ground electrode. Note that, for the purpose of holding the weight of the wire 30, a drone other than the drone 1 or a robot moving on the tower 21 may be placed on the wire 30.

The drone 1 includes a probe mechanism 10. The probe mechanism 10 is a mechanism for inspecting electrical continuity by being brought into contact with the receptor 23, and is configured to include, for example, an electrode. The wire 30 is connected to the electrode of the probe mechanism 10.

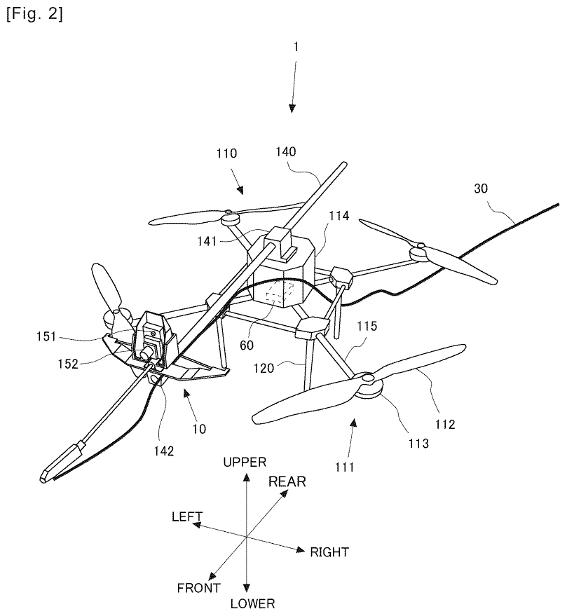

FIG. 2 is a view illustrating an example of a schematic configuration of the drone 1 including the probe mechanism 10 according to the first embodiment. The drone 1 is configured to include a main body 110. The main body 110 includes a plurality of propulsion units 111. Note that in the example illustrated in FIG. 1, four propulsion units 111 are mounted on the main body 110, but the number of propulsion units 111 is not limited to four as long as the main body 110 can fly. The propulsion units 111 each include a propeller 112 that is a rotary wing, and an actuator 113 for rotationally driving the propeller 112. Although all the propulsion units 111 mounted on the main body 110 are of the same type, the actuators 113 of the respective propulsion units 111 can be controlled independently. Therefore, it is possible to appropriately control the propulsive force obtained by each propulsion unit 111, and thus, it is possible to appropriately control the flight attitude, the flight speed, and the like of the main body 110 and the drone 1.

Here, note that in the following description, the direction of a propulsive force of the propulsion unit 111 when the drone 1 is stationary in the air, that is, a direction toward an upper side in FIG. 2 is referred to as an upward direction in an up and down direction, and a direction opposite to the propulsive force, that is, a direction toward a lower side in FIG. 2, is referred to as a downward direction in the up and down direction. The downward direction is the same as the direction of gravity. In addition, the upward direction is the tip side of the tower 21 in the direction of a central axis thereof in FIG. 1, and the downward direction is the ground side of the tower 21 in the direction of the central axis thereof in FIG. 1. Also, a direction orthogonal to the central axis of the tower 21 is defined as a horizontal direction.

Here, the main body 110 has a body 114 substantially at the center thereof, and is provided with the propulsion units 111 at the tip end of the main body 110 via a bridge 115 radially from the body 114. The four propulsion units 111 are arranged at equal intervals on a circumference around the body 114.

In addition, the bridge 115 is connected to four legs 120 that support the main body 110 when landing. The four legs 120 are arranged at equal intervals on the circumference around the body 114 and extend downward from the bridge 115. Note that in the present embodiment, four legs 120 are provided, but the number of the legs 120 is not limited to this, and it is sufficient that the number of the legs 120 is three or more.

Further, the body 114 is mounted with a battery for supplying drive power to the actuators 113 of the respective propulsion units 111, and a control device 60 for controlling power supply from the battery to the actuators 113 and the like.

The control device 60 includes a computer that has a central processing unit (CPU), a random access memory (RAM), a read only memory (ROM), and an erasable programmable ROM (EPROM), and a flight controller that controls the attitude and operation of the drone 1. The EPROM stores various programs, various tables, and the like. The CPU loads a program stored in the EPROM into a work area of the RAM to execute it, and through the execution of this program, instructions such as movement or ascent are sent to the flight controller, based on which the flight controller controls the actuators 113, etc. As a result, the CPU realizes functions that match predetermined purposes.

In addition, the control device 60 may include a communication unit that communicates with the outside via wired or wireless communication, and may receive a control command via the communication unit to switch the content of the operation in response to the control command. At this time, the control device 60 may control the propulsion units 111 by the flight controller in accordance with a control input by an operator manually operating the controller in the same manner as in a normal drone or in accordance with a flight plan stored in advance in the flight controller. Also, the control device 60 performs control to bring the probe mechanism 10 into contact with the receptor 23 based on signals from a laser sensor 151 and a camera 152 to be described later.

A support unit 141 for supporting a rod 140 to which the probe mechanism 10 is attached is provided on the upper portion of the body 114. Also, the probe mechanism 10 is arranged above a horizontal plane including the four propellers 112. The rod 140 is formed in a cylindrical shape and is arranged in the horizontal direction. Note that in the following, a direction of the central axis of the rod 140 when the drone 1 is stationary in the air, which is a direction from the support unit 141 toward the probe mechanism 10, is defined as a forward direction, and a direction from the support unit 141 toward a side at which the probe mechanism 10 is not attached is defined as a rearward direction.

The probe mechanism 10 is attached to the front end of the rod 140. Also, the probe mechanism 10 is provided with a laser sensor 151 for measuring a distance to the target object (i.e., the receptor 23) and a camera 152 for identifying the position of the receptor 23.

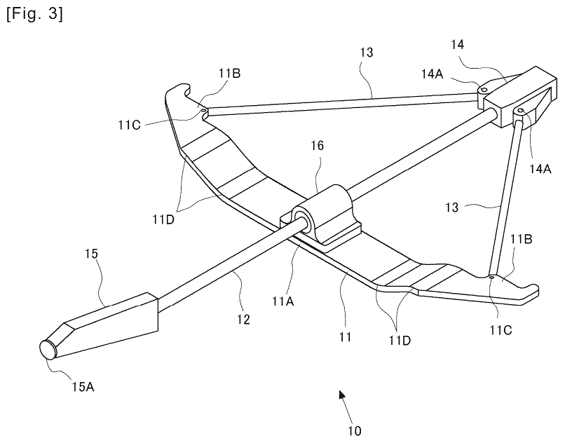

FIG. 3 is a view illustrating an example of a schematic configuration of the probe mechanism 10 according to the first embodiment. The probe mechanism 10 includes an arm 11, a shaft 12, and two springs 13. The arm 11 is fixed to the tip of the rod 140 through a shaft fixing member 142. For example, resin, metal or the like can be appropriately used as a material of the arm 11 and the shaft 12. The arm 11 is a plate-shaped member extending horizontally from the tip end of the rod 140. Note that in the following, a direction orthogonal to the up and down direction and the front and rear direction is referred to as a left and right direction. A right side and a left side are defined as a right direction and a left direction, respectively, when the drone 1 is viewed from the front side of the drone 1. Note that the arm 11 is an example of the base member.

At each of the left and right ends of the arm 11, there is formed a protruding portion 11B that protrudes rearward beyond a central portion 11A of the arm 11. Both the protruding portions 11B are respectively formed with holes 11C for attaching the springs 13 to the arm 11. Note that when each spring 13 is attached to the arm 11, a pin or a bolt may be inserted into each hole 11C, and the spring 13 may be hooked on the pin or the bolt, or an end portion of the spring 13 may be directly hooked on the hole 11C. In addition, one or more bent portions 11D are formed in such a manner that the protruding portions 11B are positioned above the central portion 11A of the arm 11. At the bent portions 11D, the arm 11 is bent, for example, in parallel to the central axis of the shaft 12. Note that, instead of bending the arm 11, a support, strut the like may be provided on the arm 11 to position the protruding portions 11B and the holes 11C above the central portion 11A.

The shaft 12 is a cylindrical member that moves relative to the arm 11 in the front and rear direction. However, its shape is not limited to a cylindrical shape, and it may be provided with a rolling groove that holds balls rolling between a guide 16 and the rolling groove, as in a ball spline or an LM guide, and prevents rotation in a roll direction. The shaft 12 is arranged with its central axis parallel to the central axis of the rod 140, so that it moves forward and backward in parallel to the central axis of the rod 140. The shaft 12 is provided at its rear end with a spring connecting portion 14 to which the springs 13 are connected. The spring connecting portion 14 has two holes 14A formed for attaching the springs 13. The holes 14A are formed on the right side and the left side of the shaft 12, respectively.

A detection unit 15 is attached to the front end of the shaft 12. The detection unit 15 according to the present embodiment is provided with an electrode 15A for the purpose of inspecting the wind power generator. The wire 30 has one end thereof connected to the electrode 15A, and the other end thereof connected to the inspection device 31 arranged on the ground. In addition, in order to suppress the position of the electrode 15A from being displaced due to slippage or the like after the electrode 15A comes into contact with the receptor 23, a structure such as an anti-slip member may be separately added around the electrode 15A.

The arm 11 is provided with the guide 16 for supporting the shaft 12 so as to be movable forward and backward in its central axis direction. The guide 16 is configured to include a rolling guide device such as a linear bush, for example. The guide, which is cylindrical in cross section, has a plurality of balls provided along the central axial direction on the inner diameter of its cylinder, thereby making it possible to guide the shaft smoothly. The friction between the guide 16 and the shaft 12 is set so that the shaft 12 can be pushed forward at least by the elastic force of the springs 13 to be described later, and so that the shaft 12 moves backward when the tip of the shaft 12 comes into contact with the receptor 23 or the like.

The springs 13 are tension springs, one ends of which are connected to the spring connecting portion 14 and the other ends of which are connected to the protruding portions 11B. One of the two springs 13 is attached to the hole 11C in the right protruding portion 11B of the arm 11 and to the right hole 14A in the spring connecting portion 14, and the other spring 13 is attached to the hole 11C in the left protruding portion 11B of the arm 11 and to the right hole 14A in the spring connecting portion 14.

Here, the central axis of each spring 13 is arranged to be orthogonal to the central axis of the shaft 12 and in the horizontal direction (i.e., in the right and left direction) when no force is applied to the shaft 12 from the outside. At this time, the amount of rearward protrusion of each protruding portion 11B is determined in such a manner that the springs 13 are not in contact with the arm 11 and the guide 16. Also, at this time, the positions of the protruding portions 11B in the up and down direction are determined in such a manner that the springs 13 are arranged in the horizontal direction. In addition, it may be constructed such that, in order to hold the shaft 12 from moving due to vibration, dead weight, or other factors even when no force is applied to the shaft 12, the positions of the protruding portions 11B and the holes 11C may be shifted forward or spacers may be provided between the guide 16 and the spring connecting portion 14, whereby the central axis of each spring 13 and the central axis of the shaft 12 may be physically restrained at positions immediately before the state in which they are orthogonal to each other, even when no external force is applied, so that the elastic forces of the springs 13 maintain the shaft 12 pressed forward with a constant force.

Also, the distance between the hole 11C of each protruding portion 11B of the arm 11 and the central axis of the shaft 12 is determined, for example, so that a required reaction force can be obtained. For example, in cases where the distance between the hole 11C of each protruding portion 11B of the arm 11 and the central axis of the shaft 12 is too short, an amount of change in the angle formed by the central axis of the shaft 12 and the central axis of each spring 13 when the shaft 12 moves will be large. Therefore, when the drone 1 comes into contact with the receptor 23, a reaction force generated suddenly increases, and it is difficult to control the attitude of the drone 1. On the other hand, in cases where the distance between the hole 11C of each protruding portion 11B of the arm 11 and the central axis of the shaft 12 is too long, the amount of change in the angle formed by the central axis of the shaft 12 and the central axis of the spring 13 when the shaft 12 moves will be small. Therefore, although the change in the reaction force becomes slow when the drone 1 comes into contact with the receptor 23, there is a possibility that a required reaction force cannot be obtained. Thus, the distance between the hole 11C of each protruding portion 11B of the arm 11 and the central axis of the shaft 12 and the spring constant are determined so that the shaft 12 is pushed by a required force. Note that the distance between the hole 11C of each protruding portion 11B of the arm 11 and each corresponding hole 14A of the spring connecting portion 14 or the length of the springs 13 can be determined in the same manner.

In the drone 1 configured in this manner, when inspecting electrical continuity from the receptor 23 of the wind power generator 20 to the ground electrode, the drone 1 flies in such a manner that the electrode 15A at the tip of the probe mechanism 10 is brought into contact with the receptor 23. For example, until the camera 152 becomes capable of capturing images of the receptor 23, the drone 1 is operated by the user through visual observation, and when the camera 152 becomes capable of capturing images of the receptor 23, the drone 1 performs autonomous flight based on the images captured by the camera 152 and the distance to the receptor 23 or the blade 22 measured by the laser sensor 151. Then, the control device 60 controls the propulsion units 111 in such a manner that the distance to the receptor 23 or the blade 22 measured by the laser sensor 151 becomes a predetermined distance while bringing the electrode 15A into contact with the receptor 23. In this way, an electrical continuity test of the receptor 23 can be performed by maintaining the state of contact between the electrode 15A and the receptor 23.

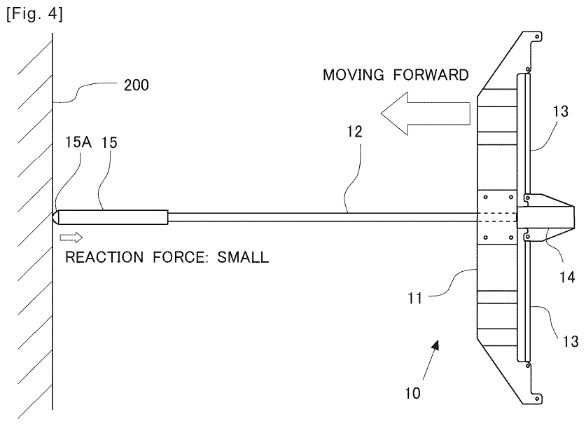

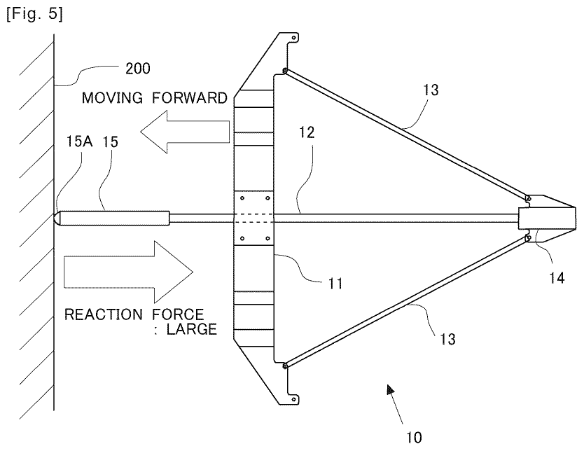

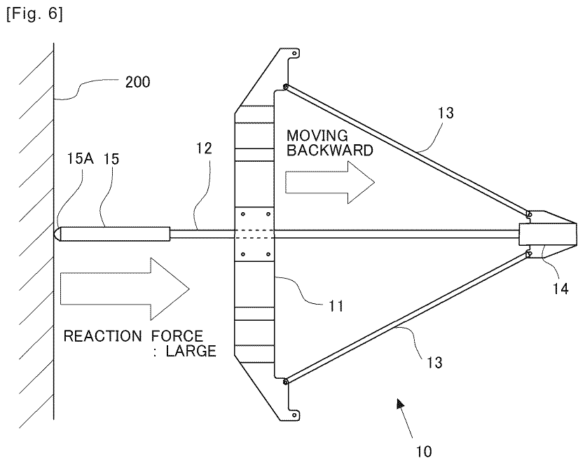

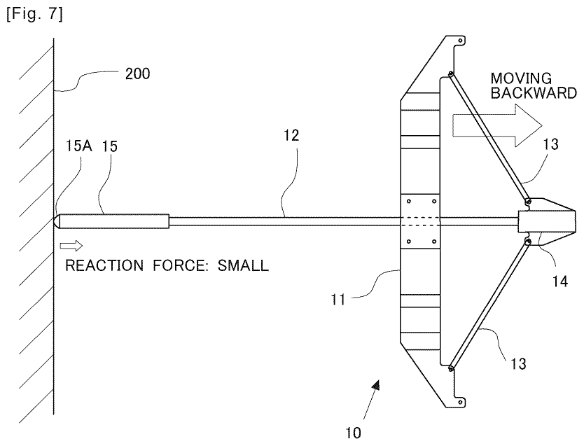

Next, the operation of bringing the probe mechanism 10 into contact with a target object 200 will be described based on FIGS. 4 through 7. FIG. 4 is a view of the probe mechanism 10 according to the embodiment as seen from above immediately after the probe mechanism 10 has come into contact with the target object 200. FIG. 5 is a view illustrating a state in which the drone 1 is moving forward after the probe mechanism 10 according to the embodiment has come into contact with the target object 200, as seen from above. FIG. 6 is a view illustrating a state immediately after the drone 1 has moved backward from the state illustrated in FIG. 5 according to the embodiment, as seen from above. FIG. 7 is a view illustrating a state in which the drone 1 according to the embodiment is moving backward, as seen from above.

As illustrated in FIG. 4, when the probe mechanism 10 comes into contact with the target object 200, the central axis of each spring 13 is orthogonal to the central axis of the shaft 12, and the spring 13 is in a state of having the shortest length. The spring 13 in this state does not generate a force in the direction of the central axis of the shaft 12. Note that the spring 13 in this state may be longer than the free length thereof. Also, in the state illustrated in FIG. 4, the front end of the spring connecting portion 14 is in contact with the rear end of the guide 16. Therefore, even before the probe mechanism 10 comes into contact with the target object 200, the shaft 12 does not move forward any further relative to the guide 16.

In the state illustrated in FIG. 4, the shaft 12 is movable backward relative to the guide 16. However, until the shaft 12 comes into contact with the target object 200, the shaft 12 is pulled back by the elastic force of the springs 13 even if the shaft 12 tries to move backward. Here, when the shaft 12 moves backward relative to the guide 16, the angle formed by the central axis of each spring 13 and the central axis of the shaft 12 becomes smaller than 90 degrees. In other words, the springs 13 are in a state connected at an angle to the shaft 12. At this time, since the springs 13 are longer than the free length thereof, an elastic force is generated in a direction in which the springs 13 contract. This elastic force includes a component in the direction of the central axis of the shaft 12, and the movement of the shaft 12 except in the direction of the central axis thereof is restricted by the guide 16, so that the shaft 12 moves in the direction of the central axis. The shaft 12 is pushed forward by this elastic force, and thus, in the state illustrated in FIG. 4, the spring connecting portion 14 is maintained in a state of being in contact with the guide 16. In this way, the state in which the central axis of each spring 13 is orthogonal to the central axis of the shaft 12 is maintained until the probe mechanism 10 comes into contact with the target object 200.

In addition, even after the shaft 12 comes into contact with the target object 200, in a state where the angle formed by the central axis of each spring 13 and the central axis of the shaft 12 is close to 90 degrees, the force of the springs 13 pushing the shaft 12 forward is small, and thus the reaction force received from the target object 200 is also small.

Also, in the state illustrated in FIG. 5, the shaft 12 receives the reaction force by pushing the target object 200, and therefore the shaft 12 moves backward relative to the guide 16. At this time, the springs 13 expand, and thus an elastic force is generated in a direction in which the springs 13 contract. Since this elastic force includes a component in the direction of the central axis of the shaft 12, the shaft 12 is urged forward. Therefore, the electrode 15A at the tip end of the shaft 12 is pressed against the target object 200. Thus, the state of contact between the electrode 15A and the target object 200 is maintained. Further, as the angle formed by the central axis of each spring 13 and the central axis of the shaft 12 becomes smaller than 90 degrees, the elastic force of the springs 13 becomes larger, and the proportion of the elastic force acting in the expansion and contraction direction also becomes larger, so that the reaction force received from the target object 200 also becomes larger.

Next, in the state illustrated in FIG. 6, the drone 1 moves in a direction away from the target object 200. At this time, since the shaft 12 is urged toward the target object 200 by the springs 13, the electrode 15A is suppressed from moving away from the target object 200. Therefore, for example, even when the attitude of the drone 1 becomes unstable and moves in the front and rear direction, the state of contact between the electrode 15A and the target object 200 can be maintained.

In addition, in the state illustrated in FIG. 7, the drone 1 is moving further away from the target object 200 than in the state illustrated in FIG. 6. In this case, the force to press the shaft 12 against the target object 200 is reduced due to the shorter length of the springs 13, but the state of contact between the electrode 15A and the target object 200 can still be maintained. Also, since the reaction force that the shaft 12 receives from the target object 200 is reduced, the drone 1 is suppressed from being pushed with a strong force, so that when the drone 1 moves away from the target object 200, the attitude of the drone 1 can be suppressed from becoming unstable.

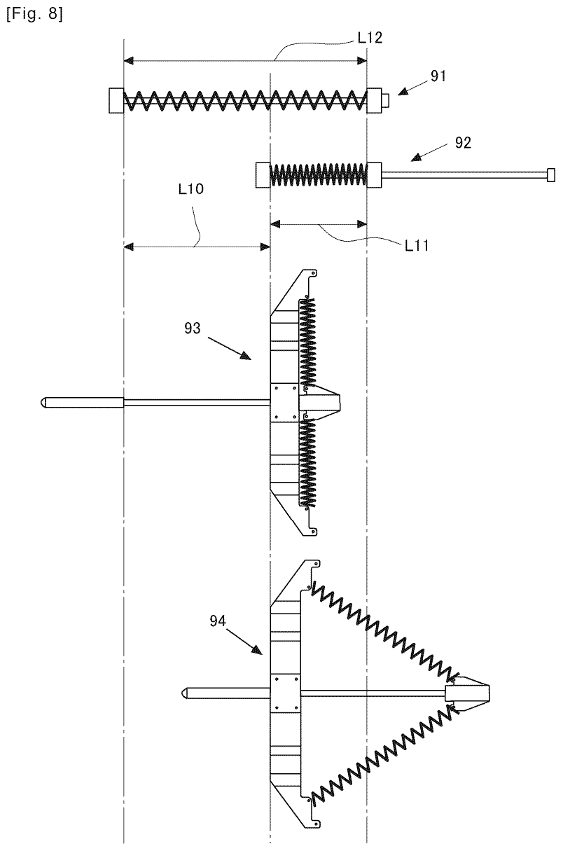

FIG. 8 is a view comparing a conventional probe using a compression spring and the probe mechanism 10 according to the first embodiment. Reference numeral 91 denotes the conventional probe using a compression spring, which is immediately before coming into contact with a target object; reference numeral 92 denotes the conventional probe using a compression spring, which is in a state of contacting the target object with the spring most compressed; reference numeral 93 denotes the probe mechanism 10 according to the present embodiment, which is in a state immediately before coming into contact with the target object; and reference numeral 94 denotes the probe mechanism 10 according to the present embodiment, which is in a state where the shaft 12 is moved most rearward with respect to the arm 11. FIG. 8 illustrates a case where an amount of stroke of the conventional probe using a compression spring is equal to an amount of stroke of the probe mechanism 10 according to the present embodiment. This amount of stroke is indicated by L10.

In the conventional probe using a compression spring (reference numerals 91, 92), the central axis of the shaft and the central axis of the compression spring are on the same line, and a space for accommodating the compressed spring (i.e., a space corresponding to the length indicated by L11 in FIG. 8) is required even in a state where the compression spring is most compressed (i.e., a state indicated by reference numeral 92). Therefore, as indicated by reference numeral 91, the space corresponding to the length indicated by L12 is required before the shaft comes into contact with the target object.

On the other hand, in the probe mechanism 10 according to the present embodiment, the springs 13, when most contracted, are arranged to be orthogonal to the shaft 12, as indicated by reference numeral 93, and thus the length required in the direction of the central axis of the shaft 12 is shortened. Therefore, it is possible to achieve space saving in the length direction of the shaft 12.

However, when a large reaction force is suddenly generated immediately after the shaft 12 is brought into contact with the receptor 23, it may be difficult to control the attitude of the drone 1. Therefore, it is preferable that the change in the reaction force be slow immediately after the shaft 12 is brought into contact with the receptor 23. On the other hand, if the drone 1 moves excessively forward after the shaft 12 is brought into contact with the receptor 23, some part, such as for example the propeller 112, other than the shaft 12 may come into contact with the blade 22 or the like of the wind power generator 20, and thus it is preferable that the drone 1 be pushed back with a large force.

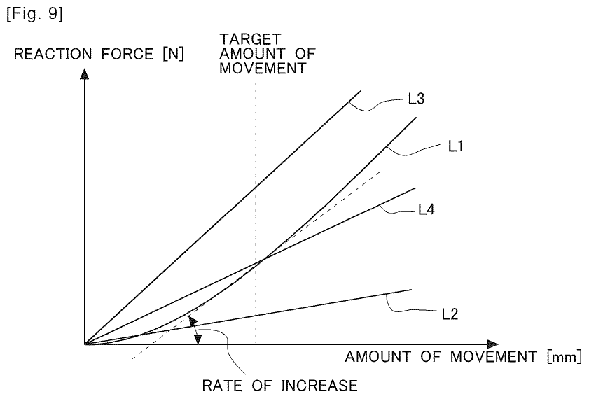

Here, FIG. 9 is a view for explaining the relationship between the amount of movement of the shaft 12 and the reaction force according to the embodiment. The horizontal axis represents the amount of movement of the shaft 12, and the vertical axis represents the reaction force that the shaft 12 receives from the target object. Line L1 shows the case of the probe mechanism 10 according to the present embodiment, line L2 shows the case of a conventional probe using a compression spring with a relatively small spring constant, line L3 shows the case of a conventional probe using a compression spring with a relatively large spring constant, and line L4 shows the case of a conventional probe using a compression spring with an intermediate spring constant. Note that the conventional probes using compression springs are the same as the probe indicated by reference numerals 91 and 92 in FIG. 8. The “target amount of movement” in FIG. 9 is, for example, 100 mm, and is an amount of movement of the shaft 12 that is a target when the wind power generator 20 is inspected. When the wind power generator 20 is inspected, the control device 60 controls the actuators 113 and the like so that the stroke of the shaft 12 becomes the target amount of movement.

As indicated by line L1, in the probe mechanism 10 according to the present embodiment, the reaction force with respect to the amount of movement of the shaft 12 has a non-linear relationship. On the other hand, in the conventional probes using the compression springs, the reaction force with respect to the amount of movement has a linear relationship as indicated by lines L2, L3, and L4. As described above, immediately after the shaft 12 comes into contact with the receptor 23, it is preferable that the amount of increase in the reaction force with respect to the amount of increase in the amount of movement of the shaft 12 (the rate of increase in the reaction force) be smaller, and hence, it is preferable that the slopes of the lines in FIG. 9 be smaller. On the other hand, in cases where the force pushing the receptor 23 with the shaft 12 becomes excessively large, it is preferable to quickly generate a large reaction force. Therefore, when the amount of movement is large, it is preferable that the rate of increase in the reaction force be larger, and therefore, it is preferable that the slopes of the lines in FIG. 9 be larger. For example, in the case of line L2, when the amount of movement is small, the rate of increase in the reaction force is small and therefore the above requirements are met, but when the amount of movement is large, the rate of increase in the reaction force is too small and therefore the above requirements are not met. On the other hand, in the case of line L3, when the amount of movement is large, the rate of increase in the reaction force is large and thus the above-described requirements are met, but when the amount of movement is small, the rate of increase in the reaction force is too large and thus the above-described requirements are not met. Further, in the case of line L4, when the amount of movement is small, the rate of increase in the reaction force may become excessively large, and when the amount of movement is large, the rate of increase in the reaction force may become excessively small, and thus the above-described requirements are not met.

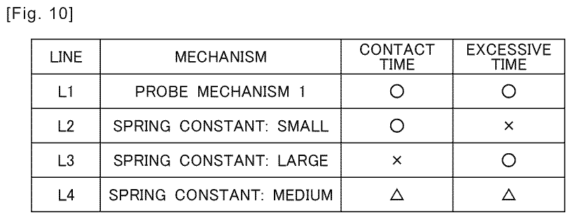

The above relationships are summarized in FIG. 10. FIG. 10 is a table summarizing whether or not the reaction forces generated in the lines L1, L2, L3, and L4 satisfy the requirements. In FIG. 10, circle marks indicate that the requirements are satisfied, and cross marks indicate that the requirements are not satisfied. Also, triangle marks indicate that the requirements are satisfied under some conditions but not completely satisfied. A “contact time” is a time immediately after the shaft 12 comes into contact with the receptor 23, and indicates, for example, a case where the amount of movement of the shaft 12 is smaller than the target amount of movement. On the other hand, an “excessive time” is a time when the force pushing the receptor 23 with the shaft 12 is excessively large, and indicates, for example, a case where the amount of movement of the shaft 12 is larger than the target amount of movement.

In FIG. 10, only the probe mechanism 10 according to the present embodiment satisfies the requirements both in the “contact time” and the “excessive time”. In this way, the probe mechanism 10 according to the present embodiment can generate an appropriate reaction force in both of the “contact time” and the “excessive time”, which cannot be realized by any conventional probe using a compression spring.

Here, note that, as described above, the rate of increase in the reaction force varies depending on the distance between the hole 11C of each protruding portion 11B of the arm 11 and the central axis of the shaft 12 (which may be the distance between the hole 11C of each protruding portion 11B of the arm 11 and the corresponding hole 14A of the spring connecting portion 14 or the length of the springs 13), and the spring constant of the springs 13. Therefore, the springs 13 may be arranged in such a manner that the rate of increase in the reaction force is less than the predetermined value when the amount of movement of the shaft 12 is smaller than the target amount of movement after the shaft 12 comes into contact with the target object, whereas the rate of increase in the reaction force is larger than the predetermined value when the amount of movement of the shaft 12 is larger than the target amount of movement. The predetermined value referred to herein is a rate of increase in the reaction force when the amount of movement of the shaft is the target amount of movement.

As described above, according to the probe mechanism 10 of the first embodiment, the length of the shaft 12 in the central axis direction thereof can be made shorter. In addition, when the amount of movement of the shaft 12 after the shaft 12 has come into contact with the receptor 23 is small, the force with which the receptor 23 is pressed by the springs 13 is small, and thus the reaction force is also small, as a result of which it is possible to suppress the reaction force from increasing rapidly to make it difficult to control the attitude of the drone 1. On the other hand, when the amount of movement of the shaft 12 is large, the force with which the springs 13 moves the shaft 12 forward becomes larger, and thus the drone 1 can be pushed back with a large force, thus making it possible to suppress component members of the drone 1 other than the shaft 12 from coming into contact with the wind power generator 20. Further, the electrode 15A can be pressed against the receptor 23 with an appropriate force by means of the springs 13, and hence it becomes possible to perform an electrical continuity test in an easy and accurate manner.

### Second Embodiment

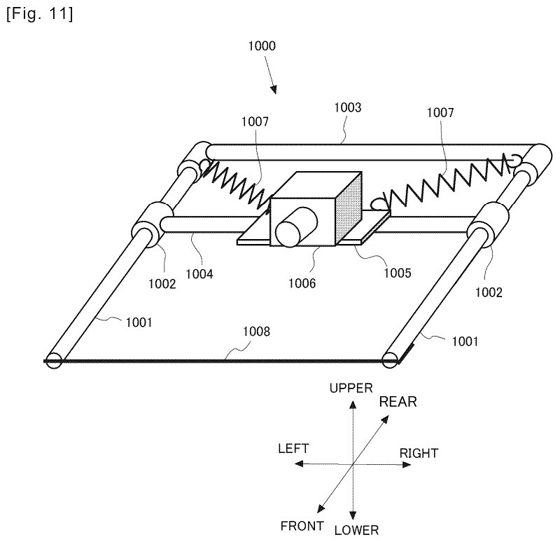

FIG. 11 is a view illustrating an example of a schematic configuration of a probe mechanism 1000 according to a second embodiment. The probe mechanism 1000 according to the present embodiment includes two shafts 1001, two guides 1002, a movable frame 1003, a fixed frame 1004, a mount 1005, a sensor 1006, two springs 1007, and a conductive wire 1008. The probe mechanism 1000 is attached to the tip end of the rod 140 described in the first embodiment.

When the probe mechanism 1000 is attached to the rod 140, the mount 1005 is fixed to the tip end of the rod 140. Alternatively, the rod 140 and the fixed frame 1004 may be fixed to each other. This fixation is performed via the shaft fixing member 142 as in the first embodiment. Also, the sensor 1006 is fixed to an upper surface of the mount 1005. The sensor 1006 is composed of the laser sensor 151 and the camera 152 described in the first embodiment. In addition, the fixed frame 1004 is fixed to the mount 1005. The fixed frame 1004 is formed in a cylindrical shape and extends in the left and right direction orthogonal to the rod 140. However, the fixed frame 1004 may be formed in a plate shape or the like, and is not limited to a cylindrical shape. The guides 1002 are provided respectively at both ends of the fixed frame 1004. The guides 1002 support the shafts 1001 respectively so as to be movable forward and backward in the front and rear direction, similar to the guide 16 described in the first embodiment. The two shafts 1001 are arranged in such a manner that the central axes thereof are parallel to the central axis of the rod 140. Also, the two shafts 1001 are arranged equidistant apart on the right and left sides of the rod 140.

The rear ends of the two shafts 1001 are connected with each other via the movable frame 1003. The movable frame 1003 is a cylindrical member arranged in parallel to the fixed frame 1004. One ends of the different springs 1007 are connected respectively to both ends of the movable frame 1003. The springs 1007 are tension springs, and the other ends of the respective springs 1007 are connected to the mount 1005. The conductive wire 1008 is stretched between the tips of the two shafts 1001. The conductive wire 1008 is pressed against the receptor 23 when the electrical continuity of the receptor 23 is inspected, as in the electrode 15A in the first embodiment. One end of the wire 30 is connected to the conductive wire 1008, and the other end of the wire 30 is connected to the inspection device 31 arranged on the ground.

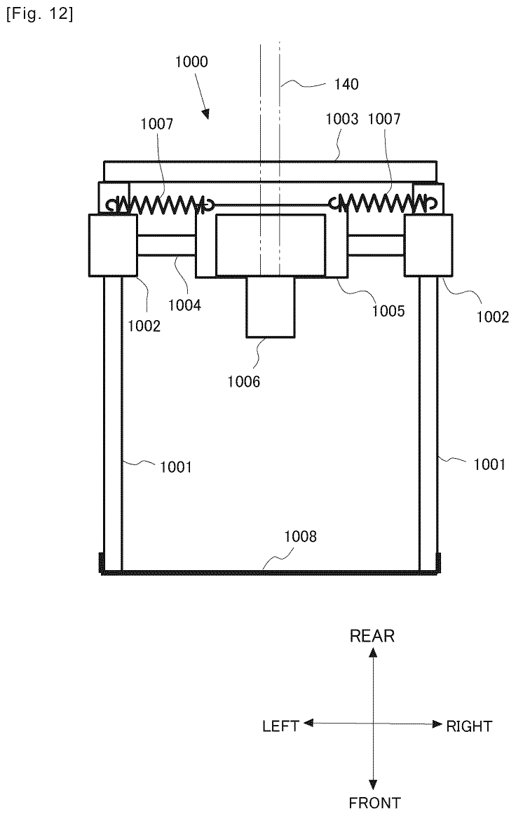

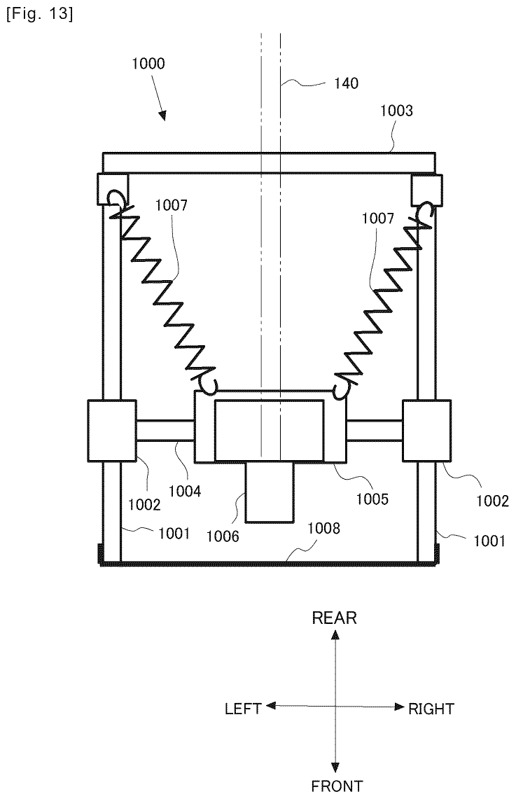

FIG. 12 is a view illustrating the probe mechanism 1000 according to the second embodiment, as seen from above, illustrating a state before the shafts 1001 and the conductive wire 1008 come into contact with the target object. In this state, the springs 1007 are arranged in the left and right direction so as to be orthogonal to the shafts 1001 and the rod 140. On the other hand, FIG. 13 is a view illustrating the probe mechanism 1000 according to the second embodiment, as seen from above, illustrating a state after the shafts 1001 or the conductive wire 1008 has come into contact with the target object. When the shafts 1001 or the conductive wire 1008 comes into contact with the target object, the shafts 1001 and the movable frame 1003 move backward relative to the mount 1005. As a result, the springs 1007 are tensioned and the angles of the springs 1007 with respect to the shafts 1001 are changed. The change in the angles of the springs 1007 generates a force to push the shafts 1001 forward. Therefore, the shafts 1001 and the conductive wire 1008 can be pressed against the target object.

As described above, according to the probe mechanism 1000 of the second embodiment, the same effects as those of the first embodiment are exhibited, and the wind power generator 20 can be inspected by the conductive wire 1008, so that even if the position of the drone 1 is deviated in the left and right direction, for example, it is possible to maintain the contact between the conductive wire 1008 and the receptor 23.

### Third Embodiment

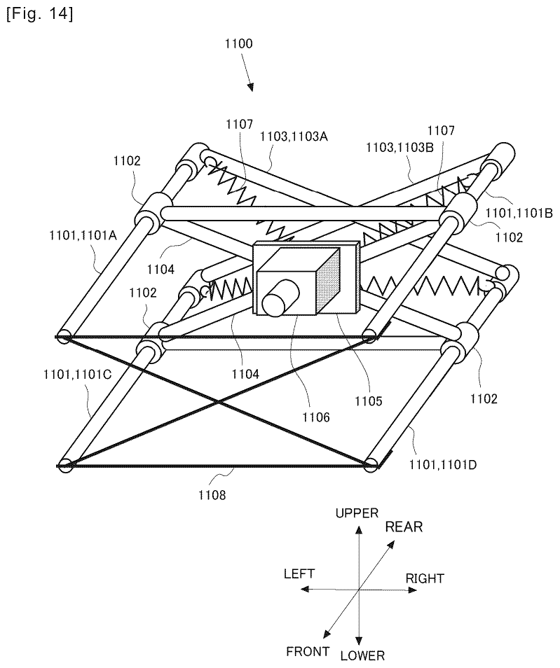

FIG. 14 is a view illustrating an example of a schematic configuration of a probe mechanism 1100 according to a third embodiment. The probe mechanism 1100 according to the present embodiment includes four shafts 1101, four guides 1102, movable frames 1103, fixed frames 1104, a mount 1105, a sensor 1106, four springs 1107, and a plurality of conductive wires 1108. The probe mechanism 1100 is attached to the tip end of the rod 140 described in the first embodiment.

The four shafts 1101 are arranged in a staggered manner in the up and down direction and in the left and right direction so as to be parallel to the rod 140. Note that two of the shafts 1101 are arranged above the mount 1105, wherein a left shaft 1101 thereof is referred to as a first shaft 1101A and a right shaft 1101 thereof is referred to as a second shaft 1101B. In addition, another two shafts 1101 are arranged below the mount 1105, wherein a right shaft 1101 thereof is referred to as a third shaft 1101C, and a left shaft 1101 is referred to as a fourth shaft 1101D. A plane containing the first shaft 1101A and the second shaft 1101B is a horizontal plane. Similarly, a plane containing the third shaft 1101C and the fourth shaft 1101D is also a horizontal plane. A plane containing the first shaft 1101A and the third shaft 1101C is orthogonal to the horizontal planes. Similarly, a plane containing the second shaft 1101B and the fourth shaft 1101D is also orthogonal to the horizontal planes. The shafts 1101 have the same length in the front and rear direction.

All the shafts 1101 are connected to each other at their rear ends via the movable frames 1103. Also, all the shafts 1101 are supported by the fixed frames 1104 via the guides 1102. The guides 1102 support the shafts 1101 so as to be movable forward and backward in the front and rear direction. The movable frames 1103 and the fixed frames 1104 are each formed by connecting a plurality of cylindrical members. However, the shape of the members may be a plate shape or the like, and is not limited to a cylindrical shape.

The mount 1105 is fixed to the fixed frames 1104. The sensor 1106 is attached to the mount 1105. In addition, one ends of the four springs 1107 are connected to the mount 1105, and the other ends of the respective springs 1107 are connected respectively to the upper, lower, left and right four corners of the movable frames 1103. The springs 1107 are arranged radially around the mount 1105. The springs 1107 are tension springs. Also, the rear ends of the respective shafts 1101 are connected to the four corners of the movable frames 1103.

The conductive wires 1108 are stretched between the tips of the four shafts 1101. The conductive wires 1108 are respectively stretched, for example, between the first shaft 1101A and the second shaft 1101B, between the first shaft 1101A and the fourth shaft 1101D, between the second shaft 1101B and the third shaft 1101C, and between the third shaft 1101C and the fourth shaft 1101D. The conductive wires 1108 are pressed against the receptor 23 when the electrical continuity of the receptor 23 is inspected, as in the electrode 15A in the first embodiment. One end of the wire 30 is connected to the conductive wires 1108, and the other end of the wire 30 is connected to the inspection device 31 arranged on the ground. In addition, the conductive wires 1108 may be replaced with a member, such as a coarse mesh, a transparent electrode, or the like, which covers a wide range and allows for confirmation of electrical continuity, as long as its properties and shape do not inhibit the operation of the sensor 1106.

In the probe mechanism 1100, the four springs 1107 are arranged on the same plane before the shafts 1101 and the conductive wires 1108 come into contact with the target object. This plane is orthogonal to the shafts 1101. On the other hand, when the shafts 1101 and the conductive wires 1108 come into contact with the target object, the shafts 1101 and the movable frames 1103 move backward relative to the mount 1105. Due to this movement, the springs 1107 are tensioned and the angles of the springs 1107 with respect to the shafts 1101 are changed, so that a part of the elastic force of the springs 1107 becomes a force that pushes the shafts 1101 forward. This force can press the shafts 1101 or the conductive wires 1108 against the target object.

As described above, according to the probe mechanism 1100 of the present embodiment, the same effects as those of the first embodiment can be achieved, and the wind power generator 20 can be inspected by the conductive wires 1108, as a result of which even if the position of the drone 1 is deviated in the up and down direction or in the horizontal direction, it is possible to maintain the contact between the conductive wires 1108 and the receptor 23.

### Other Embodiments

In the above-mentioned embodiments, the drone 1 is described that performs an electrical continuity test on a wind power generator 20, but instead, for example, by attaching an end effector other than the detection unit 15 to the tip of the shaft 12, other inspections or tasks can also be performed. In addition, in the above embodiments, a drone 1 that is flying has been described as an example of a floating moving object, but the present invention is not limited to this and can also be applied to moving objects that are not in contact with the ground, such as a moving object that moves while floating on the water surface, a moving object that moves while submerged underwater, etc. In addition, in the first embodiment, the arm 11 is arranged in the horizontal direction, but the invention is not limited to this, and the arm 11 may be arranged in the up and down direction or in the oblique direction. The shaft 12 does not necessarily have to be arranged in the horizontal direction. Also, each spring 13 may be a plurality of springs connected in series with each other. In this case, springs having different spring constants may be connected. Further, a plurality of springs may be arranged in parallel to each other.

### DESCRIPTION OF REFERENCE SIGNS

1 . . . drone, 10 . . . probe mechanism, 11 . . . arm, 12 . . . shaft, 13 . . . springs, 14 . . . spring connecting portion, 15 . . . detection unit, 16 . . . guide

1. A floating moving object comprising:
a base member to which one end of a spring is connected; and
a shaft to which the other end of the spring is connected, the shaft being configured to move relative to the base member in a direction of a central axis of the shaft when the shaft comes into contact with a target object;
wherein the spring is arranged such that a central axis of the spring is at an angle to the central axis of the shaft.

2. The floating moving object according to claim 1, wherein
the spring is a tension spring; and
the spring is arranged such that an angle formed by the central axis of the spring and the central axis of the shaft becomes smaller as the base member approaches the target object after the shaft comes into contact with the target object.

3. The floating moving object according to claim 1, wherein
wherein the base member includes a guide that supports the shaft so as to be movable in the direction of the central axis of the shaft; and
the other end of the tension spring is connected at a side from the guide in a direction in which the shaft moves relative to the base member when the shaft comes into contact with the target object.

4. The floating moving object according to claim 1, wherein
the spring is arranged such that the central axis of the spring is orthogonal to the central axis of the shaft before the shaft comes into contact with the target object.

5. The floating moving object according to claim 1, wherein
the spring is arranged such that, after the shaft comes into contact with the target object, when the amount of movement of the shaft is smaller than a target amount of movement, a ratio of an amount of increase in the reaction force to an amount of increase in the amount of movement of the shaft is less than a predetermined value, and when the amount of movement of the shaft is larger than the target amount of movement, the ratio of the amount of increase in the reaction force to the amount of increase in the amount of movement of the shaft is larger than the predetermined value.

6. A probe mechanism comprising:
a base member to which one end of a tension spring is connected; and
a shaft to which the other end of the tension spring is connected, the shaft being configured to move relative to the base member in a direction of a central axis of the shaft when the shaft comes into contact with a target object;
wherein the base member includes a guide that supports the shaft so as to be movable in the direction of the central axis of the shaft;
the other end of the tension spring is connected at a side from the guide in a direction in which the shaft moves relative to the base member when the shaft comes into contact with the target object; and
the tension spring is arranged such that a central axis of the tension spring is orthogonal to the central axis of the shaft before the shaft comes into contact with the target object, and such that an angle formed by the central axis of the tension spring and the central axis of the shaft becomes smaller as the base member approaches the target object after the shaft comes into contact with the target object.
